(19) United States
(12) Patent Application Publication
(10) Pub. No.: US 2026/0288330 A1
(43) Pub. Date: Sep. 24, 2026

(54) SELF-ADJUSTING PER-BANK REFRESH STRATEGY FOR REAL-TIME TRAFFIC OPTIMIZATION

(71) Applicant: QUALCOMM Incorporated, San Diego, CA (US)

(72) Inventors: Riccardo Iacobacci, Cork City (IE); Alain Artieri, Saint Martin D'Heres (FR); Samy Attal, Cork (IE); Sumeeth Diddigi Kulkarni, Cork (IE)

(21) Appl. No.: 19/083,156

(22) Filed: Mar. 18, 2025

(51) Int. Cl. G06F 3/06

(52) U.S. Cl. CPC G06F 3/0604; G06F 3/0655; G06F 3/0673

(57) ABSTRACT

A memory controller includes a processing system including one or more processors and one or more memories coupled to the one or more processors. The processing system is configured to determine a group of eligible refresh candidates of a memory for a per-bank refresh operation based on one or more criteria. Each eligible refresh candidate of the group of eligible refresh candidates corresponds to two or more memory banks. The processing system is further configured to select a refresh candidate from among the group of eligible refresh candidates for the per-bank refresh operation based at least in part on a refresh lateness associated with the per-bank refresh operation and to send, to the memory, a refresh command indicating the refresh candidate for the per-bank refresh operation.

### TECHNICAL FIELD

Aspects of the present disclosure relate generally to memory devices, and more particularly, to refresh operations for memory devices.

### INTRODUCTION

A computing device (e.g., a laptop, a mobile phone, etc.) may include one or several processors to perform various computing functions, such as telephony, wireless data access, and camera/video function, etc. A memory system is an important component of the computing device. The processors may be coupled to the memory system to perform the aforementioned computing functions. For example, the processors may fetch instructions from the memory system to perform the computing functions and/or to store within the memory system temporary data involved in performing these computing functions.

Memory systems may make use of memory cells that are volatile in nature. Volatile memory cells retain information for short periods of time, such as fractions of a second. A refresh operation may be performed with volatile memory cells to maintain the information for longer periods of time. In an example volatile memory cell storing information as an electrical charge, the electrical charge decays over a fraction of a second. Before the charge decays beyond the point of lost information, the memory cell may be refreshed to extend the period of time that the memory cell retains the information. In some cases, the refresh operation may be repeatedly performed to extend the period of storage of the information indefinitely, or as long as electricity is supplied to the circuit.

Such refresh operations consume power, which may impact the operation of devices operating from limited power sources, such as mobile devices operating from battery power. In addition, refresh operations may cause latency, such as by preventing or delaying read or write operations to a portion of a memory while the portion is refreshed, which may reduce device performance.

### SUMMARY

The systems, methods and devices of this disclosure each have several innovative aspects, no single one of which is solely responsible for the desirable attributes disclosed herein.

In some aspects, a memory controller includes a processing system including one or more processors and one or more memories coupled to the one or more processors. The processing system is configured to determine a group of eligible refresh candidates of a memory for a per-bank refresh operation based on one or more criteria. Each eligible refresh candidate of the group of eligible refresh candidates corresponds to two or more memory banks. The processing system is further configured to select a refresh candidate from among the group of eligible refresh candidates for the per-bank refresh operation based at least in part on a refresh lateness associated with the per-bank refresh operation and to send, to the memory, a refresh command indicating the refresh candidate for the per-bank refresh operation.

In some additional aspects, a method of operation of a memory controller includes determining a group of eligible refresh candidates of a memory for a per-bank refresh operation based on one or more criteria. Each eligible refresh candidate of the group of eligible refresh candidates corresponds to two or more memory banks. The method further includes selecting a refresh candidate from among the group of eligible refresh candidates for the per-bank refresh operation based at least in part on a refresh lateness associated with the per-bank refresh operation. The method further includes sending, to the memory, a refresh command indicating the refresh candidate for the per-bank refresh operation.

In some further aspects, a non-transitory computer-readable medium stores instructions executable by one or more processors of a memory controller to initiate, perform, or control operations. The operations include determining a group of eligible refresh candidates of a memory for a per-bank refresh operation based on one or more criteria. Each eligible refresh candidate of the group of eligible refresh candidates corresponds to two or more memory banks. The operations further include selecting a refresh candidate from among the group of eligible refresh candidates for the per-bank refresh operation based at least in part on a refresh lateness associated with the per-bank refresh operation. The operations further include sending, to the memory, a refresh command indicating the refresh candidate for the per-bank refresh operation.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

FIG. 1 is a block diagram of an example system that supports dynamic selection of memory banks for per-bank refresh operations.

FIG. 2 is a block diagram of another example system that supports dynamic selection of memory banks for per-bank refresh operations.

FIG. 3 illustrates an example of a memory system that supports dynamic selection of memory banks for per-bank refresh operations.

FIG. 4 illustrates an example of a timing diagram and a method that support dynamic selection of memory banks for per-bank refresh operations.

FIG. 5 illustrates examples of operations that may be performed by a memory controller to dynamically select memory banks for per-bank refresh operations.

FIG. 6 illustrates another example of a method that supports dynamic selection of memory banks for per-bank refresh operations.

Like reference numbers and designations in the various drawings indicate like elements.

### DETAILED DESCRIPTION

Memory devices may perform refresh operations to refresh data. Examples of refresh operations include all-bank refresh (refAB) operations and per-bank refresh (refPB) operations. In a refAB operation, all memory banks of a rank may be refreshed. In a refPB operation, some of memory banks of a rank may be concurrently refreshed without concurrently refreshing all memory banks of the rank. A refAB operation may involve interrupting read and write operations to each memory bank of a rank, which may be less efficient than a refPB operation, which may allow at least some memory banks of a rank to be accessed while other memory banks of the rank are refreshed.

In some cases, use of refPB operations may lead to refresh lateness, which may impact performance. To illustrate, if a memory bank is accessed repeatedly, a refPB of the memory bank may be deferred or postponed until the memory bank is idle. In this case, the refPB of the memory bank may be referred to as being late, and a refresh timeout may occur based on lateness. Such refresh timeout events may result in coercive refresh operations (e.g., data accesses are stalled to schedule refABs) that can heavily impact performance. Some scheduling policies may mitigate lateness by enforcing refPB operations and related bank closures irrespective of the impact on data accesses (e.g., regardless of whether the memory bank is idle), which may cause data accesses latency and worse memory efficiency.

As referred to herein, a refresh batch may be a set of refPB commands to be scheduled within a refresh time interval (tREFI), and refresh lateness may correspond to a delay between consecutive refresh batches. As an example, if a refresh batch is not completed, then lateness may be the delay since completion of the last refresh batch.

In some aspects of the disclosure, a memory controller may select memory banks for refPB operations in accordance with operating conditions. The operating conditions may include, for example, the refresh lateness intended as delay since last completed refresh batch. The criteria for selecting the optimal refPB to schedule from the pending ones in a batch are dynamically adjusted based on how late the refresh is (i.e., the delay since the last completed refresh batch) or specific traffic conditions, such as bank spread, which serves as an indicator of how the controller can schedule refPBs without disrupting data access.

By dynamically adjusting the eligibility threshold based on operating conditions, refresh timeouts and coercive refresh operations may be reduced or avoided, enhancing performance. Most importantly, the algorithm provides significant benefits by selecting more convenient times to send a refresh per-bank. For instance, it allows some flexibility in scheduling refreshes so that most refPBs can be sent when they have the least impact on data accesses. The eventual additional delay related to each refPB scheduling does not significantly increase refresh lateness or lead to more refresh timeouts, compared to stricter policies optimized for minimal refresh lateness. Benefits may include optimal and robust refresh scheduling while preserving same lateness as compared to some conventional techniques, such as strict refresh policies only optimised for minimum lateness, increased performance for different traffic classes (e.g., CPU, GPU, multimedia, etc.), for different frequencies, and for different refresh rates, and, most importantly, effective adaptive capability with inexpensive implementation.

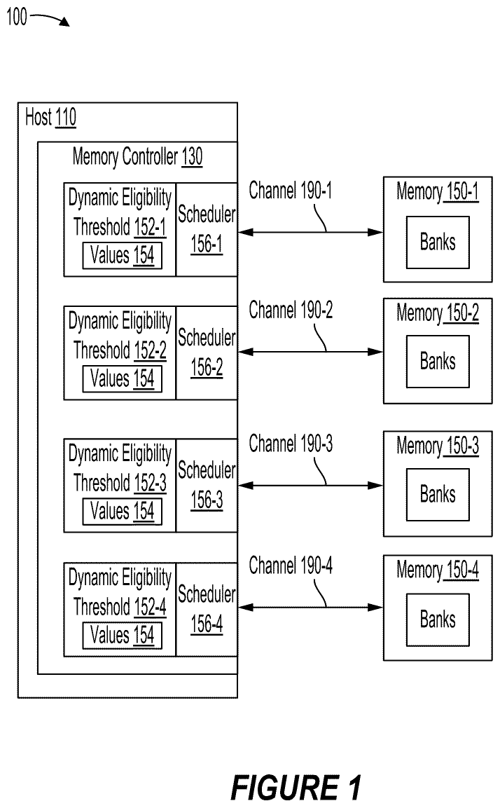

FIG. 1 is a block diagram of an example system 100 that supports dynamic selection of memory banks for per-bank refresh operations. The system 100 may include a host 110, memories 150, and channels 190 coupling the host 110 and the memories 150. The system 100 may be, for example, a device among computing systems (e.g., servers, datacenters, desktop computers), mobile computing device (e.g., laptops, cell phones, vehicles, etc.), Internet of Things devices, virtual reality (VR) systems, augmented reality (AR) systems, automobile systems (e.g., driver assistance systems, autonomous driving systems), image capture devices (e.g., stand-alone digital cameras or digital video camcorders, camera-equipped wireless communication device handsets, such as mobile telephones, cellular or satellite radio telephones, personal digital assistants (PDAs), panels or tablets, gaming devices, computing devices such as webcams, video surveillance cameras, or other devices with digital imaging or video capabilities), and/or multimedia systems (e.g., televisions, disc players, streaming devices).

The host 110 may include at least one processor, such as central processing unit (CPU), graphic processing unit (GPU), digital signal processor (DSP), multimedia engine, and/or neural processing unit (NPU). The host 110 may be configured to couple and to communicate to the memories 150 (e.g., memories 150-1 to 150-4), via channels 190 (e.g., channels 190-1 to 190-4), in performing the computing functions, such as one of data processing, data communication, graphic display, camera, AR or VR rendering, image processing, neural processing, etc. For example, the memories 150-1 to 150-4 may store instructions or data for the host to perform the computing functions.

The host 110 may include a memory controller 130, which may include schedulers 156-1, 156-2, 156-3, and 156-4. Each of the schedulers 156-1 to 156-4 may be coupled to a respective one of the memories 150-1 to 150-4 via respective channels 190-1 to 190-4. The schedulers 156-1, 156-2, 156-3, and 156-4 may select among values of dynamic eligibility thresholds 152-1, 152-2, 152-3, and 152-4 in connection with refresh operations at banks of the memories 150-1, 150-2, 150-3, and 150-4, respectively. For ease of reference, read and write are referenced from a perspective of the host 110. For example, in a read operation, the host 110 may receive via one or more of the channels 190-1-190-4 data stored from one or more of the memories 150-1 to 150-4. In a write operation, the host 110 may provide via one or more of the channels 190-1-190-4 data to be written into one or more of the memories 150-1-150-4 for storage. The memory controller 130 may be configured to control various aspects, such as logic layers, of communications to and from the memories 150-1-150-4. The memory controller 130 may be configured to control electrical characteristics (e.g., voltage levels, phase, delays, frequencies, etc.) of signals provided or received on the channels 190-1-190-4, respectively.

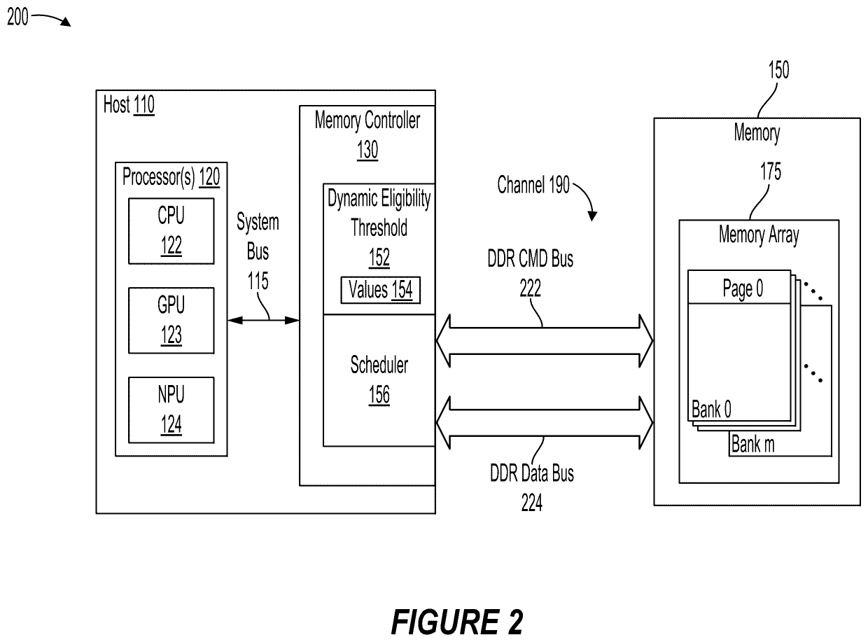

In some examples, the memories 150-1-150-4 may be DDR or LPDDR DRAM (e.g., LPDDR4, LPDDR5, LPDDR5×, LPDDR6, or DDR5, as illustrative examples). In some examples, the memories 150-1-150-4 may be different kinds of memory, such as one LPDDR5 and one LPDDR6, as illustrative examples. The host 110, the memories 150-1-150-4, and/or the channels 190-1-190-4 may operate according to an LPDDR (e.g., LPDDR5, LPDDR6) specification. In some examples, each of the channels 190-1-190-4 may include 16 bits of data (e.g., 16 DQs). In some examples, each of the channels 190-1-190-4 may operate on 32 bits of data (e.g., 32 DQs). In FIG. 1, four channels are shown, however the system 100 may include more or less channels, such as 8 or 16 channels. Additional details of an aspect of the embodiment of the system 100 for providing access to a memory system (such as one of memories 150-1-150-4 including logic and control circuit) are shown in FIG. 2.

FIG. 2 is a block diagram illustrating another example system 200 that supports dynamic selection of memory banks for per-bank refresh operations. The system 200 may include the host 110 and a memory 150. In some examples, the host 110 and the memory 150 may be coupled via a double data rate (DDR) command (CMD) bus 222 and a DDR data bus 224. In some examples, the DDR CMD bus 222 and the DDR data bus 224 may be included in a channel 190 of FIG. 1. The channel 190 between host 110 and the memory 150 may include a plurality of connections, some of which carry data (e.g., user data or application data) and some of which carry non-data (e.g., addresses and other signaling information). For example, non-data connections in channel 190 may include a data clock (e.g., WCK) used in providing data to the memory 150 and a read data strobe (e.g., RDQS) used in receiving data from the memory 150, on a per byte basis. The channel 190 may further include a data mask (e.g., DM, sometimes referred to as data mask inversion DMI to indicate multiple functions performed by the signal connection) signaling used to mask certain part of data in a write operation.

The host 110 may include at least one processor 120, which may include a CPU 122, a GPU 123, and/or an NPU 124. The host 110 may further include the memory controller 130. The memory controller 130 may couple to at least one processor 120 via a system bus 115 in performing the various computing functions. The system bus 115 may also be referred to as a bus system. The term “bus system” may provide that elements coupled to the “bus system” may exchange information therebetween, directly or indirectly. In different embodiments, the “bus system” may encompass multiple physical connections as well as intervening stages such as buffers, latches, registers, etc.

The memory 150 may include a memory array 175, which may include multiple memory cells that store values. The host 110 may read data stored in the memory array 175 and write data into the memory array 175, via the channel 190. The memory array 175 may be divided into a plurality of banks (such as banks 0 . . . m) with each bank organized as a plurality of pages (such as page 0 of bank 0).

Application or user data may be processed by the processor 120 and the memory controller 130 instructed to store and/or retrieve such data from the memory 150. For example, data may be generated during the execution of an application, such as a spreadsheet program that computes values based on other data. As another example, data may be generated during the execution of an application by receiving user input to, for example, a spreadsheet program. As a further example, data may be generated during the execution of a gaming application, which generates information regarding a representation of a scene rendered by a three-dimensional (3-D) application.

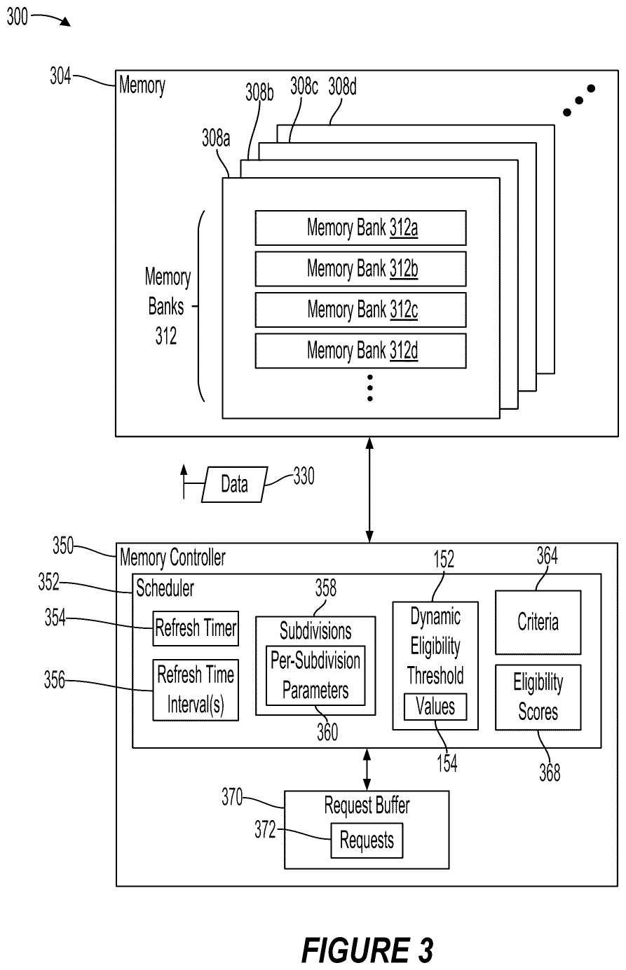

In some aspects, a memory controller may dynamically select memory banks for per-bank refresh operations in accordance with a dynamic eligibility threshold 152. For example, FIG. 2 illustrates that the memory controller 130 may operate in accordance with the dynamic eligibility threshold 152, such as using the scheduler 156. As additional examples, referring again to FIG. 1, the schedulers 156-1, 156-2, 156-3, and 156-4 may operate in accordance with dynamic eligibility thresholds 152-1, 152-2, 152-3, and 152-4, respectively. In some implementations, a memory controller may dynamically or adaptively select a particular value among values 154 of the dynamic eligibility threshold 152 and may select one or more memory banks for a refresh operation based at least in part on the particular value. Some further illustrative examples that may be associated with the dynamic eligibility threshold are described further with reference to FIG. 3.

FIG. 3 illustrates an example of a memory system 300 that supports dynamic selection of memory banks for per-bank refresh operations. In some examples, the memory system 300 may correspond to one or more features of FIG. 1 or FIG. 2. For example, the memory system 300 may correspond to one or more the memories 150-1 to 150-4 of FIG. 1 or the memory 150 of FIG. 2.

The memory system 300 may include a memory 304 and may further include a memory controller 350 coupled to the memory 304. In some examples, the memory 304 may include or may correspond to a volatile memory, such as a dynamic random access memory (DRAM). In some examples, the memory controller 350 may correspond to the memory controller 130 of FIG. 1 or FIG. 2.

The memory 304 may include one or more ranks of memory banks, such as ranks 308a, 308b, 308c, and 308d. Further, each of the ranks 308a-d may include multiple memory banks. As an example, the rank 308a may include memory banks 312, which may include memory banks 312a, 312b, 312c, and 312d. In some examples, the memory banks 312 may correspond to or may include memory banks 0-m illustrated in FIG. 2. Each memory bank of the memory banks 312 may include multiple rows of storage elements (also referred to herein as pages of storage elements or physical pages of storage elements).

The memory controller 350 may include a scheduler 352 (e.g., the scheduler 156 of FIGS. 1 and 2) and a request buffer 370. The request buffer 370 may be coupled to the scheduler 352. In some implementations, the request buffer 370 may store requests 372 associated with the memory 304, such as read requests and write requests. The requests 372 may be received, for example, from any of the one or more processors 120 of FIG. 2.

During operation, the memory system 300 may perform operations including write operations to write data 330 to the memory 304 and read operations to read the data 330 from the memory 304. For example, the data 330 may include pages of data written to any of the memory banks 312.

The memory system 300 may perform refresh operations to refresh the data 330 at the memory 304. Examples of refresh operations include all-bank refresh (refAB) operations and per-bank refresh (refPB) operations. In a refAB operation, all memory banks of a rank may be refreshed, such as by concurrently refreshing each memory bank 312 of the rank 308a. In a refPB operation, some of the memory banks 312 may be concurrently refreshed without concurrently refreshing all of the memory banks 312, such as by concurrently refreshing two memory banks of the memory banks 312. A refAB operation may involve interrupting read and write operations to each memory bank of a rank, which may be less efficient than a refPB operation, which may allow at least some memory banks of a rank to be accessed while other memory banks of the rank are refreshed.

In some examples, the memory controller 350 may determine, for a refPB operation, scores for banks based on one or more criteria 364. In some examples, the one or more criteria 364 may include or correspond to any of the criteria illustrated in the example of Table 1. It is noted that Table 1 is illustrative and non-limiting, and that other criteria may be used alternatively or in addition to the criteria provided in Table 1.

TABLE 1

| Weight | Criteria | Description |
|---|---|---|
| W₆ | noSameType | No bank candidates for the current |
| | | read-or-write (W/R) stream |
| W₅ | lowSameTypeLevel | Number of bank candidates for the current |
| | | W/R stream lower than rank average |
| W₄ | noAnyTypeHp | No high priority bank candidates |
| W₃ | noSameTypeHits | No bank candidates for the current |
| | | W/R stream hitting the currently |
| | | opened page |
| W₂ | refQual | Bank closed and time2Ref expired |
| W₁ | bankClosed | Bank closed |
| W₀ | preQual | Bank not closed AND time2Pre expired |

In the example of Table 1, the criteria may include, for a particular memory bank of a rank, one or more of whether the particular memory bank is pre-charge qualified (“preQual”), whether the particular memory bank is closed (“bankClosed”), whether the particular memory bank is refresh qualified (“refQual”), a particular quantity of pending operations associated with an open page of the particular memory bank (“noSameTypeHits”), a maximum priority of the memory requests associated with the particular memory bank (“noAnyTypeHp”), a comparison of the number of pending operations associated with the particular memory bank with the average number of pending operations associated for the banks within the same rank (“lowSameTypeLevel”), or whether the particular memory bank is associated with any pending operations (“noSameType”). Further, in Table 1, a read-or-write (W/R) stream may indicate whether the memory controller 350 is currently executing read requests or write requests from the request buffer 370.

In some implementations, the criteria indicated in Table 1 may be associated with a weighting scheme, such as weights W₀, W₁, W₂, W₃, W₄, W₅, and W₆. The weights may be selected based on the particular implementation. In some examples, the weights indicated by Table 1 may be in order of increasing weight. In such examples, W₀<W₁<W₂<W₃<W₄<W₅<W₆. In some other examples, an equal weighting scheme may be used. In such examples, W₀=W₁=W₂=W₃=W₄=W₅=W₆. Other examples are also within the scope of the disclosure. Further, it is noted that some implementations may use more, or fewer, than seven weights. The particular weighting scheme may be programmed or modified dynamically duration operation (e.g., via a software or firmware update). In some examples, the weights may be used to determine a bank score for each memory bank of the rank, such as in accordance with Equation 1:

$$bankScore [ {bank}_{i} ] = {\sum }_{j = 0}^{6} {2}^{j} \cdot {criteria}_{j} . \qquad ( Equation 1 )$$

The set of bankScores in Equation 1 may be compared to the dynamic eligibility threshold 152 to determine a group of eligible refresh candidates. In some examples, the eligible refresh candidates may also be referred to as eligible refresh commands. Further, each eligible refresh candidate may correspond to two or more memory banks of the memory 304, such as a pair of memory banks of the memory 304, which may be indicated as the ith bank and the jth bank. Accordingly, the ith bank and the jth bank may correspond to an eligible refresh candidate of the group of eligible refresh candidates. In some examples, the group of eligible refresh candidates may be determined in accordance with Equation 2:

$$refPB [ {bank}_{i} , {bank}_{j} ] is eligible ↔ min ( bankScore [ {bank}_{i} ] , bankScore [ {bank}_{j} ] ) \geq idleBankTh . \qquad ( Equation 2 )$$

In Equation 2, idleBankTh may correspond to the dynamic eligibility threshold 152. Banks that are eligible in accordance with Equation 2 may be associated with eligibility scores 368. A comparison of eligible refresh candidates may be performed based on their refresh score computed as the sum of the bankScores of the banks all satisfying the eligibility refresh threshold, such as in accordance with Equation 3:

$$refreshScore [ refPB [ {bank}_{i} , {bank}_{j} ] ] = bankScore [ {bank}_{i} ] + bankScore [ {bank}_{j} ] . \qquad ( Equation 3 )$$

In Equation 3, the refresh candidate having the highest refreshScore (among the group of eligible refresh candidates determined using Equation 2) may be targeted for a per-bank refresh operation. As noted above, each eligible refresh candidate may correspond to two or more memory banks of the memory 304, such as a pair of memory banks of the memory 304.

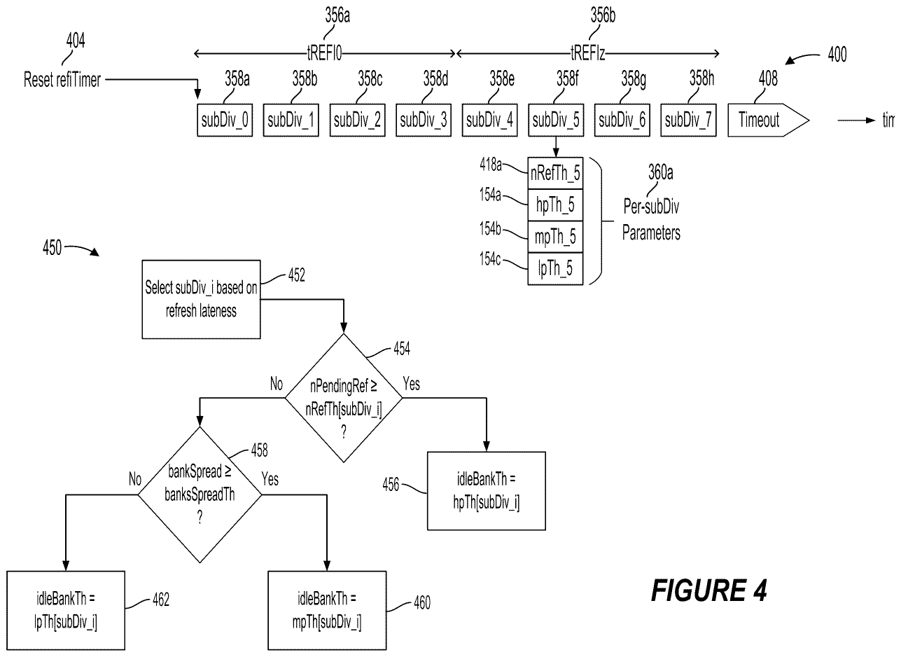

In some examples, refresh lateness (also referred to herein as delay) since the last per-bank refresh batch completion may be measured or indicated using subdivisions 358 (e.g., where each of the subdivisions 358 indicates a corresponding amount of refresh lateness). In such examples, a particular subdivision may indicate or may correspond to a current amount of lateness since the last per-bank refresh batch completion. Further, each such subdivision 358 may be associated with respective per-subdivision parameters 360. Use of different subdivisions (and different sets of per-subdivision parameters) may enable self-adjustment of coerciveness as lateness increases, such as by dynamically self-adjusting idleBankTh of Equation 2 (which may correspond to the dynamic eligibility threshold 152 of FIGS. 1-3). Some further examples are described further with reference to FIG. 4.

FIG. 4 illustrates an example of a timing diagram 400 and a method 450 that supports dynamic selection of memory banks for per-bank refresh operations. Operations described with reference to FIG. 4 may be performed by a memory controller, such as the memory 150 of FIG. 1 or FIG. 2, or the memory controller 350 of FIG. 3.

The timing diagram 400 illustrates that a refresh time interval (tREFI) 360 may be associated with multiple subdivisions, such as four subdivisions. For example, a 0th tREFI 356a may be associated with subdivisions 358a, 358b, 358c, and 358d. As another example, a zth tREFI 356b may be associated with subdivisions 358e, 358f, 358g, and 358h (where z+1 indicates a quantity of tREFIs before a timeout event). Accordingly, a tREFI may be divided into s subdivisions, where s is an integer greater than one. Further, in the example of FIG. 4, s may correspond to four subdivisions. Other examples are also within the scope of the disclosure. For example, a tREFI may be divided into more than, or fewer than, four subdivisions. Further, in some examples, the 0th tREFI 356a may be associated with a different quantity of subdivisions as compared to the zth tREFI 356b. In addition, one or more features described herein (such as the particular quantity of subdivisions of a tREFI) may be configurable (e.g., via a firmware update) and also may be modified dynamically duration operation (e.g., by the memory controller 350).

The timing diagram 400 also illustrates that each subdivision 358 may be associated with respective per-subdivision parameters 360. For example, the subdivision 358f may be associated with per-subdivision parameters 360a.

In the example of FIG. 4, the per-subdivision parameters 360a may include a pending refresh threshold 418a (nRefTh_5). In some examples, the pending refresh threshold 418a may enable a high pressure (HP) zone of operation, where “pressure” may refer to an amount of coerciveness (or “aggressiveness”) in scheduling refresh operations. To illustrate, if a quantity of pending refresh operations exceeds the refresh threshold 418a, the scheduler 352 of FIG. 3 may operate in accordance with the HP zone, such as by reducing a value of the dynamic eligibility threshold 152 (so that more banks are eligible to be refreshed). In some such examples, the scheduler 352 may need to preempt one or more other operations, such as a read operation or a write operation, to enable a refresh operation and to prevent increasing refresh lateness. In other examples, if the quantity of pending refresh operations fails to exceed the refresh threshold 418a, the scheduler 352 of FIG. 3 may operate in accordance with another zone, such as a medium pressure (MP) zone or a low pressure (LP) zone, which may be associated with greater values of the dynamic eligibility threshold 152 (as compared to the HP zone) and thus fewer eligible banks.

FIG. 4 also illustrates that the per-subdivision parameters 360a may include one or more values of the dynamic eligibility threshold 152. The one or more values of the dynamic eligibility threshold 152 may include, for example, values associated with the high pressure (HP) zone, the medium pressure (MP) zone, and the low pressure (LP) zone. Such zones may be associated with respective amounts of urgency, where each such amount of urgency is associated with a different value of the dynamic eligibility threshold 152 (e.g., where increasing urgency is associated with reduced values of the dynamic eligibility threshold 152 so that more banks are eligible to be refreshed). The one or more values of the dynamic eligibility threshold 152 may include at least a first value 154a (hpTh_5) corresponding to a first refresh urgency, a second value 154b (mpTh5) corresponding to a second refresh urgency less than the first refresh urgency, and a third value 154c (lpTh_5) corresponding to a third refresh urgency less than the second refresh urgency.

In some examples, the refresh timer 354 of FIG. 3 may be initialized (e.g., reset), at 404. In some examples, the refresh timer 354 may indicate an amount of time between refresh batches, and the refresh timer 354 may be updated (or initialized) upon completion of a refresh batch.

After being initialized, the refresh timer 354 may count a particular quantity of tREFIs until determining a timeout event 408 (if no batch of refresh operations is completed with a particular time interval, such as a particular quantity of tREFIs). In the example of FIG. 4, the particular quantity of tREFIs may correspond to z. To reduce or avoid instances of the timeout event 408, memory banks may be selected for another refresh operation in accordance with one or more techniques described herein. For example, memory banks may be selected in accordance with the method 450.

The method 450 may include determining, based on refresh lateness since the last refresh batch completion, a subdivision from among a plurality of subdivisions, at 452. The plurality of subdivisions may include, for example, the subdivisions 358a-h. In some examples, the memory controller 350 may identify the value indicated by the refresh timer 354, and the value may correspond to the amount of delay. To further illustrate, in some examples, the subdivision may be selected in accordance with Equation 4:

$$refreshLateness = ⌊ \frac{refiTimer}{tRefi} \cdot nSubDivs ⌋ . \qquad ( Equation 4 )$$

In the example of Equation 4, refreshLateness may correspond to the amount of delay between performing the prior per-bank refresh batch and the subsequent per-bank refresh batch. Further, refiTimer may indicate a current value of the refresh timer 354, where the refresh timer 354 may be incremented by an amount tRefi any time a per-bank refresh batch is completed, and where nSubDivs indicates a quantity of subdivisions since the prior refresh batch completion. In addition, n may indicate an index associated with the subdivision (e.g., 0, 1, 2, 3, 4, 5, 6, or 7).

The method 450 may further include determining whether a quantity of pending refresh operations associated with a rank satisfies the pending refresh threshold associated with the subdivision, at 454. For example, the memory controller 350 may identify the quantity of pending refreshing operations associated with the rank 308a, such as by determining how many refresh operations are queued for the rank 308a. In some examples, the subdivision may correspond to the subdivision 358f, and the pending refresh threshold may correspond to the pending refresh threshold 418a. In such examples, the memory controller 350 may compare the quantity of pending refreshes to the pending refresh threshold 418a.

In some examples, the quantity of pending refresh operations may exceed the pending refresh threshold. In such examples, the method 450 may further include setting the dynamic eligibility threshold 152 to the first value 154a, at 456.

In some other examples, the quantity of pending refresh operations may not exceed the pending refresh threshold. In such examples, the method 450 may further include determining whether a bank spread associated with the rank satisfies a bank spread threshold, at 458. The bank spread may indicate, for example, an amount of activity associated with different banks within the rank 308a, such as a quantity of pending operations queued for such banks in the rank 308a. As an example, the bank spread may correspond to a quantity of banks having at least one pending request at the request buffer 370, such as a read request or a write request. In some implementations, the memory controller 350 may dynamically self-adjust refresh operation in accordance with refresh lateness and the bank spread.

In some examples, the bank spread may exceed the bank spread threshold. In such examples, the method 450 may further include setting the dynamic eligibility threshold 152 to the second value 154b, at 460. To illustrate, if the bank spread exceeds the bank spread threshold, then the rank may be associated with a relatively large quantity of pending operations. Such a large quantity of pending operations may preempt refresh operations and may therefore potentially increase refresh lateness. Accordingly, if the bank spread exceeds the bank spread threshold, the scheduler 352 of FIG. 3 may schedule refresh operations more coercively (or “aggressively”) using the second value 154b, which may avoid increasing lateness that may result from such requests preempting refresh operations.

In some other examples, the bank spread may not exceed the bank spread threshold. In such examples, the method 450 may further include setting the dynamic eligibility threshold 152 to the third value 154c, at 462. To illustrate, if the bank spread fails to exceed the bank spread threshold, then the rank may be associated with a relatively low quantity of pending operations. In such examples, the scheduler 352 of FIG. 3 may not need to schedule refresh operations coercively (or “aggressively”) and may lower the dynamic eligibility threshold 152 to the third value 154c.

After setting a value of the dynamic eligibility threshold 152 (e.g., any of the values 154a-c), the method 450 may further include selecting memory banks for a refresh operation in accordance with the value of the dynamic eligibility threshold 152. For example, the memory controller 350 may select, in accordance with the value of the dynamic eligibility threshold 152, eligible refresh candidates among the pending refresh operations (i.e., Equation 2). If multiple refresh candidates are eligible, the memory controller 350 may select candidates with the highest refresh scores.

To further illustrate, in some examples, the first value for each subdivision (e.g., the first value 154a for the subdivision 358f) may correspond to a high pressure zone. A high pressure zone may increase lateness responsiveness while also accounting for nPendingRef. A high pressure zone may involve coercive scheduling when not enough refPBs have been sent in previous subDivs and based on current lateness. The second value for each subdivision (e.g., the second value 154b for the subdivision 358f) may correspond to a medium pressure zone. A medium pressure zone may avoid unnecessary accumulation of lateness according to traffic characteristics. Further, in connection with a medium pressure zone, the bank spread may be used as a proxy of an activity level (or “busyness”) of memory banks to lower a refresh eligibility threshold idleBankTh and fast-track pending refPBs. In some cases, lowering the refresh eligibility threshold may avoid some undesirable scenarios, such as in the case of a high bank spread (e.g., where many banks are busy), which may be associated with accumulated lateness without providing good chances of sending the refPB later on with lower data accesses interferences. For example, when the bank spread is high (and many banks are associated with requests), waiting for an idle bank may increase lateness, which can reduce performance.

The third value of each subdivision (e.g., the third value 154c for the subdivision 358f) may correspond to a low pressure zone. A low pressure zone may be associated with more flexible and performance-driven refresh scheduling. In connection with a lower pressure zone, a scheduler may select refPBs while reducing or minimizing interference with data accesses based on current lateness.

In some examples, values of the per-subdivision parameters 360 may decrease as lateness increases (e.g., with increasing values of i) in order to avoid a large amount of lateness. In Table 2, greater values of i may correspond to greater refresh lateness. To illustrate, Table 2 illustrates examples of values of the per-subdivision parameters 360 for different subdivisions. It is noted that the example of Table 2 is illustrative and that the particular values are non-limiting.

TABLE 2

| | i = 0: | i = 1: | i = 2: | i = 3: | i = 4: | i = 5: | i = 6: | i = 7: |
|---|---|---|---|---|---|---|---|---|
| hpTh_i: | 0 | 0 | 0 | 0 | 0 | 0 | 0 | 0 |
| mpTh_i: | 24 | 24 | 24 | 24 | 0 | 0 | 0 | 0 |
| lpTh_i: | 92 | 92 | 88 | 88 | 24 | 24 | 0 | 0 |
| nRefTh_i: | 8 | 7 | 6 | 5 | 4 | 3 | 2 | 1 |

In Table 2, values of hpTh_i, mpTh_i, lpTh_i, and nRefTh_i may be more “aggressive” as lateness increases (e.g., with increasing values of i). As lateness increases, nRefTh may decrease because, at the beginning of a new subdivision, a certain number of refresh operations may be assumed to have been completed in the previous subdivisions (where the number is defined as nRefTh). When this does not happen and the number of pending refresh operations exceeds nRefTh for the current subdivision, a High Pressure Zone (eligibility threshold selected is hpTh) may be initiated and more coercive actions may be taken to mitigate the fact that we have more pending refresh operations than expected given the current lateness/subdivision.

For example, as lateness increases, nRefTh_i may decrease in order to decrease the quantity of pending refresh operations (e.g., to decrease nPendingRef). In some examples, tREFI may be divided into four subdivisions, and the eight values for i may correspond to the eight subdivisions encompassing two tREFIs. As another example, by decreasing values of hpTh_i, mpTh_i, and lpTh_i as lateness increases, excessive postponing of refresh scheduling may be avoided when approaching refresh timeout (e.g., the timeout event 408).

Table 3 illustrates examples of values of idleBankTh for different conditions, which may correspond to one or more conditions described with reference to Table 1. It is noted that the example of Table 3 is illustrative and that the particular values are non-limiting.

TABLE 3

| idleBankTh: | Condition(s): |
|---|---|
| 92 | noSameType AND noAnyTypeHp AND noSameTypeHits |
| | AND refQual |
| 88 | noSameType AND noAnyTypeHp AND noSameTypeHits |
| 24 | noAnyTypeHp AND noSameTypeHits |
| 0 | Bank always eligible |

Accordingly, in some aspects, scheduling coerciveness may be self-adjusted based on one or more of traffic characteristics unfavorable to unimpactful refresh scheduling (e.g., a medium pressure zone) or cumulative lateness and the quantity of pending per-bank refresh commands. Lateness may be constrained by enforcing per-bank refreshes at a regular and programmable pace. A value of nRefTh may be selected for each subdivision sub_i to determine how many pending refresh operations we expect to have by the beginning of sub_i. Whenever the number of pending refresh operations exceeds nRefTh for the current subdivision, a high pressure zone may be initiated. In some implementations, responsiveness to traffic, lateness, and pending per-bank refreshes may be programmed based on one or more factors. In some examples, the one or more factors may include one or more of a refresh rate (e.g., 1×, 0.25×, etc.), client bandwidth, or memory access patterns (e.g., bank spread, bytes per activates, etc.). In some implementations, a configurable set of parameters may enable a configurable tradeoff between lateness and DDR performance (e.g., where lateness may be decreased at the expense of DDR performance, and vice versa). To further illustrate, the number of subdivisions and nRefTh, hpTh, mpTh and lpTh for each subdivision may be adjusted based on a tradeoff between refresh scheduling for robustness (e.g., minimum lateness) at the expense of DDR performance or vice versa. Such a choice may depend on different factors like the ones mentioned before (i.e., refresh rate, memory access patterns, traffic classes, etc.). Accordingly, some aspects may enable a particular combination of scheduling robustness and flexibility for various traffic patterns, and refresh operation of a memory controller may be adjustable based on one or more of a traffic class, a refresh rate, a system type, a memory technology, or one or more other parameters or features. A bank scoring method may optionally be used in connection with the self-adjusting mechanism.

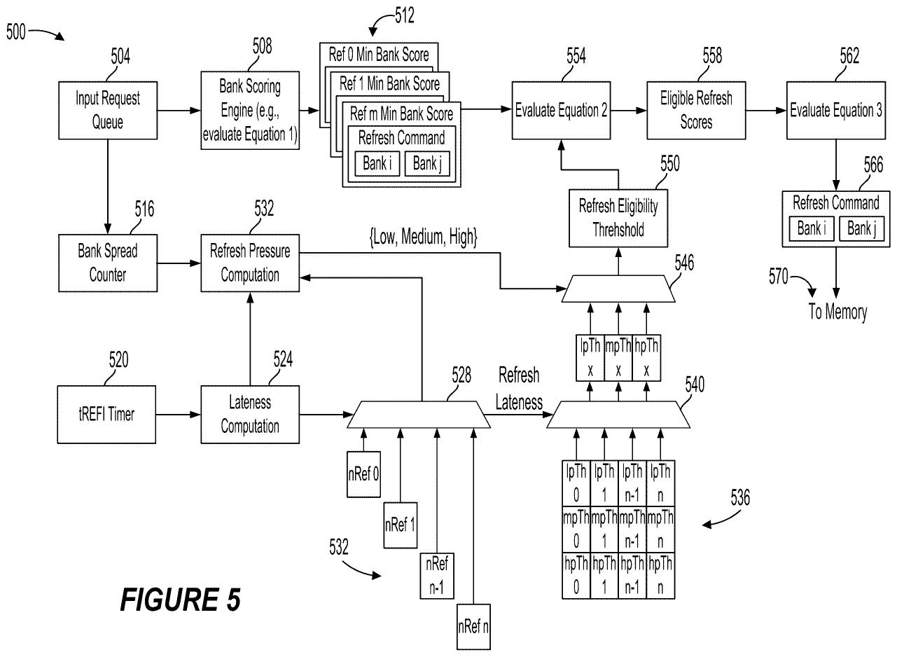

FIG. 5 illustrates examples of operations 500 that may be performed by a memory controller to dynamically select memory banks for per-bank refresh operations. In some examples, the operations 500 may be performed by the memory controller 350. In another example, the operations 500 may be performed by the memory controller 130. In the example of FIG. 5, n+1 may correspond to a number of tREFI subdivisions, and m+1 may correspond to a number of refresh candidates in a batch.

The operations 500 may include receiving a request at an input request queue, at 504. For example, the request may correspond to a request for a read operation or a write operation. Further, the request may be stored at the request buffer 370 of FIG. 3. The operations 500 may further include inputting the request to a bank scoring engine, at 508. The bank scoring engine may determine bank scores 512. In some examples, the bank scoring engine may determine the bank scores 512 by evaluating Equation 1.

The operations 500 may further include determining an amount of refresh lateness, at 524, based on a tREFI timer 520. In some examples, the tREFI timer 520 may correspond to the refresh timer 354 of FIG. 3.

The operations 500 may further include selecting, at 528, among nRef values 532 (e.g., nRef values 0, 1, . . . n−1, and n) based on the amount of refresh lateness. To illustrate, in some examples, the nRef values 532 may correspond to respective subdivisions, such as the subdivisions 358. Accordingly, the selected nRef value may indicate a subdivision of the subdivisions 358.

The operations 500 may further include determining a refresh pressure, at 532. In some examples, the refresh pressure may be determined based on the amount of refresh lateness, based on the selected nRef value, and based on a value indicated by a bank spread counter 516. To illustrate, referring again to FIG. 4, an amount of refresh lateness may correspond to one of the subdivisions 358a-h, such as the subdivision 358f. Each such subdivision may be associated with per-subdivision parameters, such as the per-subdivision parameters 360a. Using the per-subdivision parameters, refresh pressure may be selected in accordance with the method 450, such as by selecting a HP zone (e.g., at 456), a MP zone (e.g., at 460), or a LP zone (e.g., at 462).

The operations 500 may further include selecting, at 540, among thresholds 536 based on the selected nRef value. For example, in some implementations, each subdivision may be associated with parameters including a respective nRef value of the nRef values 532, a respective low pressure threshold (lpTh), a respective medium pressure threshold (mpTh), and a respective high pressure threshold (hpTh). In the example of FIG. 5, the selected thresholds may by indicated as lpTh x, mpTh x, and hpTh x, where x corresponds to 0, 1, . . . n−1, or n.

The operations 500 may further include selecting, at 546, a refresh eligibility threshold 550 based on the selected thresholds and further based on the refresh pressure. To illustrate, if the refresh pressure corresponds to low pressure, medium pressure, or high pressure, the refresh eligibility threshold 550 may correspond to lpTh x, mpTh x, or hpTh x, respectively. In some examples, the refresh eligibility threshold 550 may correspond to the dynamic eligibility threshold 152 or a particular value 154 of the dynamic eligibility threshold 152.

The operations 500 may further include determining eligible refresh scores 558, such as by performing an evaluation, at 554, of Equation 2 based on the refresh eligibility threshold 550. In some examples, the eligible refresh scores 558 may correspond to the eligibility scores 368.

The operations 500 may further include evaluating Equation 3, at 562, based on the eligible refresh scores 558 to determine a refresh command 566. The refresh command 566 may indicate a pair of refresh-eligible memory banks, such as memory banks i and j. In some other implementations, the refresh command 566 may indicate a different quantity of banks, such as more than two banks.

The operations 500 may further include outputting the refresh command 566 to a memory, at 570. For example, the refresh command 566 may be sent to the memory 150 or the memory 304.

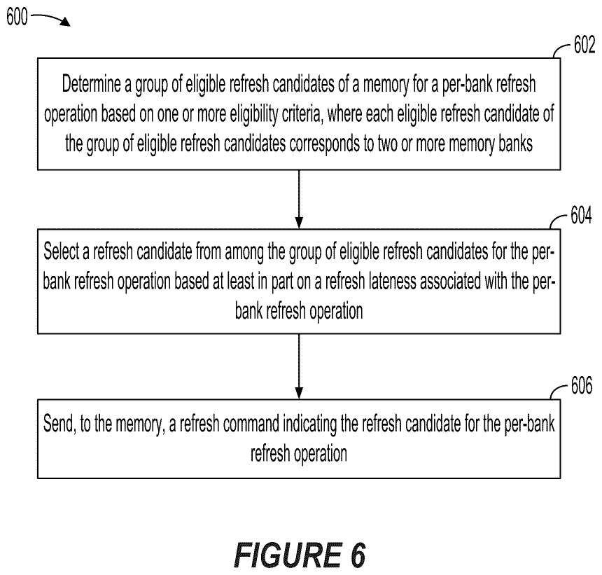

FIG. 6 illustrates an example of a method 600 that supports dynamic selection of memory banks for per-bank refresh operations. In some examples, the operations of the method 600 may be performed by the memory controller 350, such as by the scheduler 352. In another example, operations of the method 600 may be performed by the memory controller 130, such as by the scheduler 156.

The method 600 includes determining a group of eligible refresh candidates of a memory for a per-bank refresh operation based on one or more criteria, where each eligible refresh candidate of the group of eligible refresh candidates corresponds to two or more memory banks, at 602. In some examples, the group of eligible refresh candidates may include, for example, the group of eligible refresh candidates may be determined based on evaluating Equation 2, by performing the evaluation at 554 of FIG. 5, or both. In such examples, the group of eligible refresh candidates may correspond to the set of refresh candidates that satisfy Equation 2.

The method 600 further includes selecting a refresh candidate from among the group of eligible refresh candidates for the per-bank refresh operation based at least in part on a refresh lateness associated with the per-bank refresh operation, at 604. For example, a subdivision 358 may be selected based on the amount of refresh lateness, and per-subdivision parameters 360 associated with the subdivision 360 may be used to set a value 154 of the dynamic eligibility threshold 152 (e.g., as described with reference to FIG. 4). Further, the refresh candidate may be selected from among the group of eligible refresh candidates based at least in part on the value 154 of the dynamic eligibility threshold 152.

The method 600 further includes sending, to the memory, a refresh command indicating the refresh candidate for the per-bank refresh operation, at 606. For example, the refresh command may correspond to the refresh command 566, which may indicate a two or more refresh-eligible memory banks, such as memory banks i and j.

In some examples, a memory controller may include a processing system configured to perform one or more operations described herein, such as one or more operations of the method 600. The processing system may include one or more processors and one or more memories coupled to the one or more processors. In some examples, the one or more processors may include the scheduler 156 or the scheduler 352. In some examples, the one or more memories may include the request buffer 370. Alternatively, or in addition, a non-transitory computer-readable medium may store instructions executable by one or more processors to initiate, perform, or control one or more operations described herein. In some examples, the non-transitory computer-readable medium may include the memory 304 or another memory. In some examples, the one or more processors may include the scheduler 156 or the scheduler 352.

In a first aspect, a memory controller includes a processing system includes one or more processors and one or more memories coupled to the one or more processors. The processing system is configured to determine a group of eligible refresh candidates of a memory for a per-bank refresh operation based on one or more criteria. Each eligible refresh candidate of the group of eligible refresh candidates corresponds to two or more memory banks. The processing system is further configured to select a refresh candidate from among the group of eligible refresh candidates for the per-bank refresh operation based at least in part on a refresh lateness associated with the per-bank refresh operation and to send, to the memory, a refresh command indicating the refresh candidate for the per-bank refresh operation.

In a second aspect, in combination with the first aspect, the processing system is further configured to determine the group of eligible refresh candidates in accordance with an eligibility threshold that is based on one or more of the refresh lateness or a bank spread associated with the memory.

In a third aspect, in combination with one or more of the first aspect or the second aspect, the processing system is further configured to determine, based on the refresh lateness, a subdivision from among a plurality of subdivisions associated with one or more refresh time intervals (tREFIs). The subdivision is associated with a pending refresh threshold and a plurality of values of the eligibility threshold, the plurality of values including at least a first value corresponding to a high pressure zone, a second value corresponding to a medium pressure zone, and a third value corresponding to a low pressure zone.

In a fourth aspect, in combination with one or more of the first aspect through the third aspect, the processing system is further configured to determine whether a quantity of pending refresh operations associated with a rank of the memory exceeds the pending refresh threshold and, based on the quantity of pending refresh operations exceeding the pending refresh threshold, set the eligibility threshold to the first value.

In a fifth aspect, in combination with one or more of the first aspect through the fourth aspect, the processing system is further configured to determine whether a quantity of pending refresh operations associated with a rank of the memory exceeds the pending refresh threshold and, based on the quantity of pending refresh operations failing to exceed the pending refresh threshold, determine whether a bank spread associated with the rank satisfies a bank spread threshold indicating a quantity of memory banks of the memory associated with at least one pending request.

In a sixth aspect, in combination with one or more of the first aspect through the fifth aspect, the processing system is further configured to set, based on the bank spread exceeding the bank spread threshold, the eligibility threshold to the second value.

In a seventh aspect, in combination with one or more of the first aspect through the sixth aspect, the processing system is further configured to determine set, based on the bank spread failing to exceed the bank spread threshold, the eligibility threshold to the third value of the plurality of values.

In an eighth aspect, in combination with one or more of the first aspect through the seventh aspect, the processing system is further configured to determine dynamically self-adjusting refresh operation of the memory controller in accordance with the refresh lateness and a bank spread associated with the memory, the bank spread indicating a quantity of memory banks of the memory that are associated with one or more pending requests.

In a ninth aspect, in combination with one or more of the first aspect through the eighth aspect, the processing system is further configured to adjust refresh operation of the memory controller based on one or more of a traffic class, a refresh rate, a system type, or a memory technology.

In a tenth aspect, in combination with one or more of the first aspect through the ninth aspect, the processing system is further configured to perform a prior refresh batch before the per-bank refresh operation, and the refresh lateness corresponds to an amount of delay since completion of the prior refresh batch.

In an eleventh aspect, a method of operation of a memory controller includes determining a group of eligible refresh candidates of a memory for a per-bank refresh operation based on one or more criteria. Each eligible refresh candidate of the group of eligible refresh candidates corresponds to two or more memory banks. The method further includes selecting a refresh candidate from among the group of eligible refresh candidates for the per-bank refresh operation based at least in part on a refresh lateness associated with the per-bank refresh operation. The method further includes sending, to the memory, a refresh command indicating the refresh candidate for the per-bank refresh operation.

In a twelfth aspect, in combination with the eleventh aspect, the group of eligible refresh candidates is determined in accordance with an eligibility threshold that is based on one or more of the refresh lateness or a bank spread associated with the memory.

In a thirteenth aspect, in combination with one or more of the eleventh aspect through the twelfth aspect, the method further includes determining, based on the refresh lateness, a subdivision from among a plurality of subdivisions associated with one or more refresh time intervals (tREFIs). The subdivision is associated with a pending refresh threshold and a plurality of values of the eligibility threshold, the plurality of values including at least a first value corresponding to a high pressure zone, a second value corresponding to a medium pressure zone, and a third value corresponding to a low pressure zone.

In a fourteenth aspect, in combination with one or more of the eleventh aspect through the thirteenth aspect, the method further includes determining whether a quantity of pending refresh operations associated with a rank of the memory exceeds the pending refresh threshold. The method further includes, based on the quantity of pending refresh operations exceeding the pending refresh threshold, setting the eligibility threshold to the first value.

In a fifteenth aspect, in combination with one or more of the eleventh aspect through the fourteenth aspect, the method further includes determining whether a quantity of pending refresh operations associated with a rank of the memory exceeds the pending refresh threshold. The method further includes, based on the quantity of pending refresh operations failing to exceed the pending refresh threshold, determining whether a bank spread associated with the rank satisfies a bank spread threshold indicating a quantity of memory banks of the memory associated with at least one pending request.

In a sixteenth aspect, in combination with one or more of the eleventh aspect through the fifteenth aspect, the method further includes, based on the bank spread exceeding the bank spread threshold, setting the eligibility threshold to the second value.

In a seventeenth aspect, in combination with one or more of the eleventh aspect through the sixteenth aspect, the method further includes, based on the bank spread failing to exceed the bank spread threshold, setting the eligibility threshold to the third value of the plurality of values.

In an eighteenth aspect, a non-transitory computer-readable medium stores instructions executable by one or more processors of a memory controller to initiate, perform, or control operations. The operations include determining a group of eligible refresh candidates of a memory for a per-bank refresh operation based on one or more criteria. Each eligible refresh candidate of the group of eligible refresh candidates corresponds to two or more memory banks. The operations further include selecting a refresh candidate from among the group of eligible refresh candidates for the per-bank refresh operation based at least in part on a refresh lateness associated with the per-bank refresh operation. The operations further include sending, to the memory, a refresh command indicating the refresh candidate for the per-bank refresh operation.

In a nineteenth aspect, in combination with the eighteenth aspect, the operations further include dynamically self-adjusting refresh operation of the memory controller in accordance with the refresh lateness and a bank spread associated with the memory, the bank spread indicating a quantity of memory banks of the memory that are associated with one or more pending requests.

In a twentieth aspect, in combination with one or more of the eighteenth aspect through the nineteenth aspect, the operations further include adjusting refresh operation of the memory controller based on one or more of a traffic class, a refresh rate, a system type, or a memory technology.

In the FIGURES, a single block may be described as performing a function or functions: The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including components such as a processor, memory, and the like.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or process disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the FIGURES, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

1. A memory controller comprising:
a processing system comprising one or more processors and one or more memories coupled to the one or more processors, the processing system configured to:
determine a group of eligible refresh candidates of a memory for a per-bank refresh operation based on one or more criteria, wherein each eligible refresh candidate of the group of eligible refresh candidates corresponds to two or more memory banks;
select a refresh candidate from among the group of eligible refresh candidates for the per-bank refresh operation based at least in part on a refresh lateness associated with the per-bank refresh operation, wherein the refresh lateness corresponds to an amount of delay since completion of a prior refresh batch; and
send, to the memory, a refresh command indicating the refresh candidate for the per-bank refresh operation.

2. The memory controller of claim 1, wherein the processing system is further configured to determine the group of eligible refresh candidates in accordance with an eligibility threshold that is based on one or more of the refresh lateness or a bank spread associated with the memory.

3. The memory controller of claim 2, wherein the processing system is further configured to determine, based on the refresh lateness, a subdivision from among a plurality of subdivisions associated with one or more refresh time intervals (tREFIs), wherein the subdivision is associated with a pending refresh threshold and a plurality of values of the eligibility threshold, the plurality of values including at least a first value corresponding to a high pressure zone, a second value corresponding to a medium pressure zone, and a third value corresponding to a low pressure zone.

4. The memory controller of claim 3, wherein the processing system is further configured to:
determine whether a quantity of pending refresh operations associated with a rank of the memory exceeds the pending refresh threshold; and
based on the quantity of pending refresh operations exceeding the pending refresh threshold, set the eligibility threshold to the first value.

5. The memory controller of claim 3, wherein the processing system is further configured to:
determine whether a quantity of pending refresh operations associated with a rank of the memory exceeds the pending refresh threshold; and
based on the quantity of pending refresh operations failing to exceed the pending refresh threshold, determine whether a bank spread associated with the rank satisfies a bank spread threshold indicating a quantity of memory banks of the memory associated with at least one pending request.

6. The memory controller of claim 5, wherein the processing system is further configured to set, based on the bank spread exceeding the bank spread threshold, the eligibility threshold to the second value.

7. The memory controller of claim 5, wherein the processing system is further configured to set, based on the bank spread failing to exceed the bank spread threshold, the eligibility threshold to the third value of the plurality of values.

8. The memory controller of claim 1, wherein the processing system is further configured to determine dynamically self-adjusting refresh operation of the memory controller in accordance with the refresh lateness and a bank spread associated with the memory, the bank spread indicating a quantity of memory banks of the memory that are associated with one or more pending requests.

9. The memory controller of claim 1, wherein the processing system is further configured to adjust refresh operation of the memory controller based on one or more of a traffic class, a refresh rate, a system type, or a memory technology.

10. The memory controller of claim 1, wherein the processing system is further configured to perform the prior refresh batch before the per-bank refresh operation.

11. A method of operation of a memory controller, the method comprising:
determining a group of eligible refresh candidates of a memory for a per-bank refresh operation based on one or more criteria, wherein each eligible refresh candidate of the group of eligible refresh candidates corresponds to two or more memory banks;
selecting a refresh candidate from among the group of eligible refresh candidates for the per-bank refresh operation based at least in part on a refresh lateness associated with the per-bank refresh operation, wherein the refresh lateness corresponds to an amount of delay since completion of a prior refresh batch; and
sending, to the memory, a refresh command indicating the refresh candidate for the per-bank refresh operation.

12. The method of claim 11, wherein the group of eligible refresh candidates is determined in accordance with an eligibility threshold that is based on one or more of the refresh lateness or a bank spread associated with the memory.

13. The method of claim 12, further comprising determining, based on the refresh lateness, a subdivision from among a plurality of subdivisions associated with one or more refresh time intervals (tREFIs), wherein the subdivision is associated with a pending refresh threshold and a plurality of values of the eligibility threshold, the plurality of values including at least a first value corresponding to a high pressure zone, a second value corresponding to a medium pressure zone, and a third value corresponding to a low pressure zone.

14. The method of claim 13, further comprising:
determining whether a quantity of pending refresh operations associated with a rank of the memory exceeds the pending refresh threshold; and
based on the quantity of pending refresh operations exceeding the pending refresh threshold, setting the eligibility threshold to the first value.

15. The method of claim 13, further comprising:
determining whether a quantity of pending refresh operations associated with a rank of the memory exceeds the pending refresh threshold; and
based on the quantity of pending refresh operations failing to exceed the pending refresh threshold, determining whether a bank spread associated with the rank satisfies a bank spread threshold indicating a quantity of memory banks of the memory associated with at least one pending request.

16. The method of claim 15, further comprising, based on the bank spread exceeding the bank spread threshold, setting the eligibility threshold to the second value.

17. The method of claim 15, further comprising, based on the bank spread failing to exceed the bank spread threshold, setting the eligibility threshold to the third value of the plurality of values.

18. A non-transitory computer-readable medium storing instructions executable by one or more processors of a memory controller to initiate, perform, or control operations, the operations comprising:
determining a group of eligible refresh candidates of a memory for a per-bank refresh operation based on one or more criteria, wherein each eligible refresh candidate of the group of eligible refresh candidates corresponds to two or more memory banks;
selecting a refresh candidate from among the group of eligible refresh candidates for the per-bank refresh operation based at least in part on a refresh lateness associated with the per-bank refresh operation, wherein the refresh lateness corresponds to an amount of delay since completion of a prior refresh batch; and
sending, to the memory, a refresh command indicating the refresh candidate for the per-bank refresh operation.

19. The non-transitory computer-readable medium of claim 18, wherein the operations further comprise dynamically self-adjusting refresh operation of the memory controller in accordance with the refresh lateness and a bank spread associated with the memory, the bank spread indicating a quantity of memory banks of the memory that are associated with one or more pending requests.

20. The non-transitory computer-readable medium of claim 18, wherein the operations further comprise adjusting refresh operation of the memory controller based on one or more of a traffic class, a refresh rate, a system type, or a memory technology.
